(19) United States
(12) Patent Application Publication
(10) Pub. No.: US 2007/0262399 A1
(43) Pub. Date: Nov. 15, 2007

(54) SEALING SPACER TO REDUCE OR ELIMINATE LATERAL OXIDATION OF A HIGH-K GATE DIELECTRIC

(76) Inventors: Gilbert Dewey, Hillsboro, OR (US); Justin S. Sandford, Tigard, OR (US); Nancy Zelick, Portland, OR (US); Jack T. Kavalieros, Portland, OR (US); Suman Datta, Beaverton, OR (US)

Correspondence Address: INTEL CORPORATION;c/o INTELLEVATE, LLC, P.O. BOX 52050, MINNEAPOLIS, MN, 55402, US

(21) Appl. No.: 11/382,515

(22) Filed: May 10, 2006

(51) Int. Cl. H01L 29/78; H01L 21/336

(52) U.S. Cl. 257/410; 438/591; 438/287; 257/412

(57) ABSTRACT

Embodiments of the invention provide a device with a metal gate, a high-k gate dielectric layer and reduced or eliminated oxide layer beneath the high-k gate dielectric layer. A spacer adjacent a gate stack may act as an oxygen barrier to prevent the oxide from forming.

### BACKGROUND

### Background of the Invention

MOS field-effect transistors with very thin silicon dioxide based gate dielectrics may experience unacceptable gate leakage currents. Forming the gate dielectric from certain high-k dielectric materials, instead of silicon dioxide, can reduce gate leakage. When conventional processes are used to form such transistors, a silicon dioxide transition layer with birds beak formation may form between the high-k dielectric and the substrate, between the spacer and gate stack and between the spacer and substrate. The presence of that transition layer may unfavorably contribute to the overall electrical thickness of the gate dielectric stack.

### BRIEF DESCRIPTION OF THE DRAWINGS

FIG. 1 is a cross sectional side view that illustrates the semiconductor device of one embodiment of the present invention.

FIG. 2 is a flow chart that illustrates how the device of FIG. 1 may be formed.

FIG. 3 is a cross sectional side view that that illustrates an embodiment with a blanket high-k dielectric layer on the substrate, a blanket first electrode layer on the blanket high-k dielectric layer, and a blanket second electrode layer on the blanket first electrode layer.

FIG. 4 is a cross sectional side view that illustrates the blanket high-k dielectric layer, the blanket first electrode layer, and the blanket second electrode layer after they have been patterned to form the high-k gate dielectric layer, first electrode layer, and the second electrode layer.

FIG. 5 is a cross sectional side view that illustrates ion implantation.

FIG. 6 is a cross sectional side view that illustrates the device after at least a portion of the damaged region has been removed.

FIG. 7 is a cross sectional side view that illustrates a blanket layer of spacer material formed on the gate stack and substrate.

FIG. 8 is a cross sectional side view that illustrates the device after it has been annealed to recrystallize some or all of the remaining amorphous regions of the substrate.

FIG. 9 is a cross sectional side view that illustrates an ILD (interlayer dielectric) layer formed and planarized on the device.

FIG. 10 is a cross sectional side view that illustrates removal of the first and second electrodes.

FIG. 11 is a cross sectional side view that illustrates replacement of the first and second electrode layers with first and second replacement electrode layers.

FIG. 12 illustrates a system in accordance with one embodiment of the present invention.

### DETAILED DESCRIPTION

In various embodiments, an apparatus and method relating to the formation of a substrate are described. In the following description, various embodiments will be described. However, one skilled in the relevant art will recognize that the various embodiments may be practiced without one or more of the specific details, or with other replacement and/or additional methods, materials, or components. In other instances, well-known structures, materials, or operations are not shown or described in detail to avoid obscuring aspects of various embodiments of the invention. Similarly, for purposes of explanation, specific numbers, materials, and configurations are set forth in order to provide a thorough understanding of the invention. Nevertheless, the invention may be practiced without specific details. Furthermore, it is understood that the various embodiments shown in the figures are illustrative representations and are not necessarily drawn to scale.

Reference throughout this specification to “one embodiment” or “an embodiment” means that a particular feature, structure, material, or characteristic described in connection with the embodiment is included in at least one embodiment of the invention, but do not denote that they are present in every embodiment. Thus, the appearances of the phrases “in one embodiment” or “in an embodiment” in various places throughout this specification are not necessarily referring to the same embodiment of the invention. Furthermore, the particular features, structures, materials, or characteristics may be combined in any suitable manner in one or more embodiments. Various additional layers and/or structures may be included and/or described features may be omitted in other embodiments.

Various operations will be described as multiple discrete operations in turn, in a manner that is most helpful in understanding the invention. However, the order of description should not be construed as to imply that these operations are necessarily order dependent. In particular, these operations need not be performed in the order of presentation. Operations described may be performed in a different order than the described embodiment. Various additional operations may be performed and/or described operations may be omitted in additional embodiments.

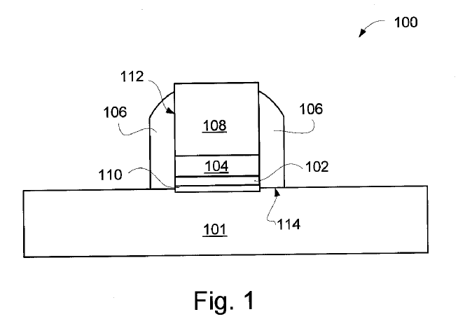

FIG. 1 is a cross sectional side view that illustrates the semiconductor device 100 of one embodiment of the present invention. That semiconductor device may have a gate electrode stack, which may include a high-k gate dielectric layer 102 on substrate 101, a first electrode layer 104 on the high-k gate dielectric layer 102, and a second electrode layer 108 on the first electrode layer 108. In an embodiment, the second electrode layer 108 may comprise polysilicon. In an embodiment, the first electrode layer 104 may comprise a capping material to separate the polysilicon from the high-k gate dielectric layer 102 material. In another embodiment, the first electrode layer 104 may comprise a metal material having a desired work function for the device 100 once it is completed. In other embodiments, there may be more than two electrode layers, while in yet other embodiments, there may only be one electrode layer on the high-k gate dielectric layer 102. There may be a thin oxide or oxynitride layer 110 on the substrate 101 between the gate stack 102, 104, 108 and the substrate 101 in some embodiments. This thin oxide layer 110 may be as thin as a monolayer of oxide in some embodiments. In another embodiment, the thin oxide layer 110 may have two layers of oxide, while in other embodiments the oxide layer 110 may be thicker. In some embodiments, the oxide layer 110 may have a thickness between about 3 angstroms and about 6 angstroms, although another embodiment may have an oxide layer 110 with a different thickness.

The substrate 101 may comprise any material that may serve as a foundation upon which a semiconductor device may be built. In this embodiment, substrate 101 is a silicon containing substrate. The substrate 101 may be a bulk substrate 101, such as a wafer of single crystal silicon, a silicon-on-insulator (SOI) substrate 101, such as a layer of silicon on a layer of insulating material on another layer of silicon, or another type of substrate 101. The device 100 formed on the substrate 101 may be a transistor in some embodiments. The device 100 may be a planar transistor on a bulk substrate 101, a planar transistor on an SOI substrate 101, a FIN-FET transistor on a bulk substrate 101, a FIN-FET transistor on an SOI substrate 101, a tri-gate transistor on a bulk substrate 101, a tri-gate transistor on an SOI substrate, or another type of transistor or other device 100.

The high-k gate dielectric layer 102 may comprise, for example, hafnium oxide, hafnium silicon oxide, lanthanum oxide, lanthanum aluminum oxide, zirconium oxide, zirconium silicon oxide, titanium oxide, tantalum oxide, barium strontium titanium oxide, barium titanium oxide, strontium titanium oxide, yttrium oxide, aluminum oxide, lead scandium tantalum oxide, and lead zinc niobate. Although a few examples of materials that may be used to form the high-k gate dielectric layer 102 are described here, the high-k gate dielectric layer 102 may be made from other materials that serve to reduce gate leakage in other embodiments.

In some embodiments, the high-k gate dielectric layer 102 may be less than about 40 angstroms thick. In other embodiments, the high-k gate dielectric layer 102 may be between about 5 angstroms and about 20 angstroms thick.

The high-k gate dielectric layer 102 may have a k-value higher than about 7.5 in some embodiments. In other embodiments, the high-k gate dielectric layer 102 may have a k-value higher than about 10. In other embodiments, the high-k gate dielectric layer 102 may comprise a material such as Al₂O₃ with a k-value of about 12, or may comprise a material with a higher k-value than that. In other embodiments, the high-k gate dielectric layer 102 may have a k-value between about 15 and about 25, e.g. HfO₂. In yet other embodiments, the high-k gate dielectric layer 102 may have a k-value even higher, such as 35, 80 or even higher.

The first electrode layer 104 may comprise a metal gate electrode layer 104 in some embodiments. This metal gate electrode layer 104 may comprise any conductive material from which metal gate electrodes may be derived. Materials that may be used to form n-type metal gate electrodes include: hafnium, zirconium, titanium, tantalum, aluminum, their alloys (e.g., metal carbides that include these elements, i.e., hafnium carbide, zirconium carbide, titanium carbide, tantalum carbide, and aluminum carbide), and aluminides (e.g., an aluminide that comprises hafnium, zirconium, titanium, tantalum, or tungsten). Materials for forming p-type metal gate electrodes include: ruthenium, palladium, platinum, cobalt, nickel, and conductive metal oxides, e.g., ruthenium oxide. Alternatively, a mid-gap metal gate material, e.g. stoichiometric titanium nitride or tantalum nitride, may be used in some embodiments, such as embodiments in which the substrate 101 is a SOI substrate 101.

In some embodiments, metal NMOS gate electrodes may have a workfunction that is between about 3.9 eV and about 4.2 eV. In some embodiments, metal PMOS gate electrodes may have a workfunction that is between about 4.9 eV and about 5.2 eV. In some embodiments, metal mid-gap gate electrodes may have a workfunction between those of NMOS and PMOS metal gate electrodes. A metal gate electrode 104 that is formed on a high-k gate dielectric layer 102 may consist essentially of a homogeneous metal layer. Alternatively, relatively thin n-type or p-type metal layers (like those listed above) may generate the lower part of the metal gate electrode, with the remainder of the metal gate electrode comprising another metal or metals, e.g., a metal that may be easily polished like tungsten, aluminum, titanium, or titanium nitride. Although a few examples of materials for forming a metal gate electrode are identified here, such a component may be made from many other materials, as will be apparent to those skilled in the art.

As mentioned above, the second gate electrode layer 108 may comprise polysilicon. This polysilicon electrode layer 108 may comprise a doped polysilicon material in some embodiments, with dopants chosen to be appropriate to the device 100 type. In other embodiments, the second gate electrode layer 108 may comprise other materials. In yet other embodiments, the gate stack may only include one gate electrode layer 104 on the high-k dielectric layer 102, in which case the second gate electrode layer 108 would be absent.

There may be spacers 106 on either side of the gate stack. The spacers 106 may be consist of a material or materials that are substantially entirely free of oxygen in some embodiments. For example, in an embodiment the spacers 106 may comprise a nitride material. In other embodiments, the spacers 106 may comprise other materials.

There may be a boundary region 112 between each spacer 106 and the gate stack (between spacer 106 and the second electrode layer 108, the first electrode layer 104, and the high-k gate dielectric layer 102) that may be substantially entirely free of an oxide layer in an embodiment. There may be a boundary region 114 between each spacer and the substrate 101 that may also be substantially entirely free of an oxide layer in an embodiment. In some embodiments, the spacers 106 may be in direct contact with one or more layers of the gate stack (the high-k gate dielectric layer 102, the first electrode layer 104, and the second electrode layer 108) and/or may be in direct contact with the substrate 101. There may be substantially no birds beak structure at the left and right edges (as illustrated in FIG. 1) of the gate stack in the region between the high-k gate dielectric layer 102 and the substrate 101. There may be substantially no birds beak structure at the left and right edges (as illustrated in FIG. 1) of the gate stack in the region between the high-k gate dielectric layer 102 and the first electrode layer 104. The lack of oxide materials between the spacers and gate stack and/or substrate, and/or lack of birds beak structures may provide a device 100 with better performance than devices 100 that have such structures. Such structures may provide, or be indicative of transport of oxygen, which may result in a thicker transitional oxide layer 110, which may reduce device 100 performance.

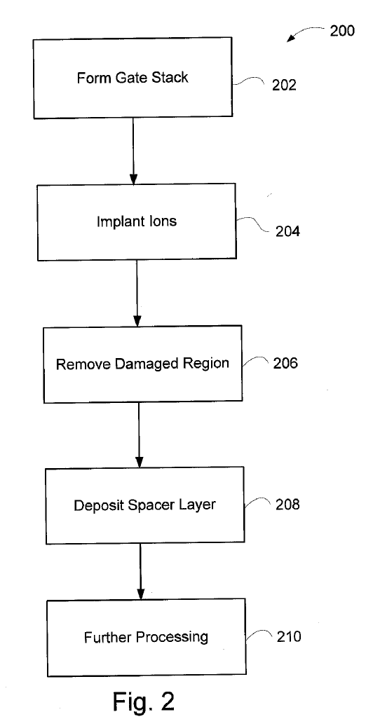

FIG. 2 is a flow chart 200 that illustrates how the device 100 of FIG. 1 may be formed, according to one embodiment of the present invention. The gate stack, including the high-k gate dielectric layer 102, first electrode layer 104, and second electrode layer 108 may be formed 202. Ions may be implanted 204 to form tip junction regions in the substrate 101, which may result in damaged regions at a top portion of the implanted region. In some embodiments, some or all of the damaged regions may be removed 206, although in other embodiments this process may be omitted. The spacer layer 106 may then be deposited 208, followed by further processing 210. The farther processing 210 may include annealing to recrystallize regions of the substrate 101 that were amorphized by the implantation 204 process, forming interlayer dielectric (ILD) layer(s) and interconnects, and/or other processes.

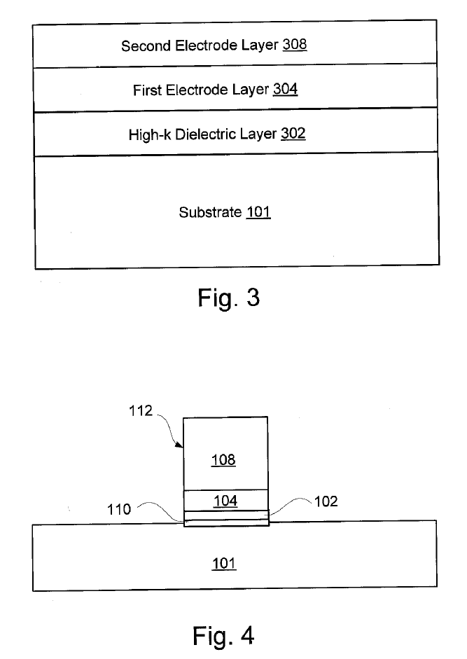

FIGS. 3 through 11 are cross sectional side views that illustrate the formation of the device 100 as described above with respect to FIG. 2, as well as some additional processing that may be performed in some embodiments.

FIG. 3 is a cross sectional side view that that illustrates an embodiment with a blanket high-k dielectric layer 302 on the substrate 101, a blanket first electrode layer 304 on the blanket high-k dielectric layer 302, and a blanket second electrode layer 308 on the blanket first electrode layer 304. In an embodiment, the blanket high-k gate dielectric layer 302 may be formed on the substrate 101 by an atomic layer chemical vapor deposition (“ALCVD”) process, although in other embodiments other processes may be used. In an ALCVD process, a growth cycle may be repeated until a high-k gate dielectric layer 102 of a desired thickness is created. Such a growth cycle may comprise the following sequence in an embodiment. Steam is introduced into a CVD reactor for a selected pulse time, followed by a purging gas. A precursor (e.g., an organometallic compound, a metal chloride or other metal halide) is then pulsed into the reactor, followed by a second purge pulse. (A carrier gas that comprises nitrogen or another inert gas may be injected into the reactor at the same time.)

While operating the reactor at a selected pressure and maintaining the substrate at a selected temperature, steam, the purging gas, and the precursor are, in turn, fed at selected flow rates into the reactor, By repeating this growth cycle—steam, purging gas, precursor, and purging gas—multiple times, one may create a blanket high-k gate dielectric layer 302 of a desired thickness on the substrate 101. The pressure at which the reactor is operated, the gases' flow rates, and the temperature at which the substrate is maintained may be varied depending upon the application and the precursor that is used. The CVD reactor may be operated long enough to form the blanket high-k gate dielectric layer 302 with the desired thickness. In some embodiments, the blanket high-k gate dielectric layer 302 may be less than about 40 angstroms thick. In other embodiments, the blanket high-k gate dielectric layer 302 may be between about 5 angstroms and about 20 angstroms thick.

After forming the blanket high-k gate dielectric layer 302 on the substrate 101, the blanket first electrode layer 304 may be formed on the blanket high-k gate dielectric layer 302. Any suitable method may be used. In an embodiment where the blanket first electrode layer 304 is a blanket metal gate electrode layer 304, the blanket metal gate electrode layer 304 may be formed using conventional metal deposition processes, e.g. CVD or PVD processes, by using ALCVD, or another suitable method. Materials besides metal may be used for the first electrode layer 304. For example, in an embodiment where the first electrode layer 304 will be removed and replaced later by a metal gate electrode layer and the second electrode layer 308 comprises polysilicon, any suitable material that keeps the high-k gate dielectric layer 302 from undesirably interacting with the second electrode layer 308 may be used.

After forming the blanket first electrode layer 304 on the high-k gate dielectric layer 302, the blanket second electrode layer 308 may be formed on the blanket first electrode layer 304. Any suitable method may be used to form the blanket second electrode layer 308. In an embodiment, the blanket second electrode layer 308 may comprise polysilicon, although other materials may be used in other embodiments. Some embodiments may lack the blanket second electrode layer 308 and include only the first blanket electrode layer 304. Still other embodiments may include additional blanket electrode layers (not shown) on the blanket second electrode layer 308.

FIG. 4 is a cross sectional side view that illustrates the blanket high-k dielectric layer 302, the blanket first electrode layer 304, and the blanket second electrode layer 308 after they have been patterned to form the high-k gate dielectric layer 102, first electrode layer 104, and the second electrode layer 108. Any suitable method may be used to pattern the blanket layers 302, 304, 308. Combined, the high-k gate dielectric layer 102, first electrode layer 104, and the second electrode layer 108 may be considered a gate stack, with a sidewall boundary 112.

FIG. 5 is a cross sectional side view that illustrates ion 502 implantation. The ions 502 may be implanted into the substrate 101 to form doped regions 504. These doped regions 504 may be tip junctions of a device after the device is completed. The implantation of ions 502 may result in a region 506 near the top surface of the substrate 101 that is damaged and/or changed from a crystalline to an at least partially amorphous structure. In some cases the choice of implantion ions and/or the amorphization of the surface layer may enhance the oxidation rate or the rate of oxidation diffusion through such a layer.

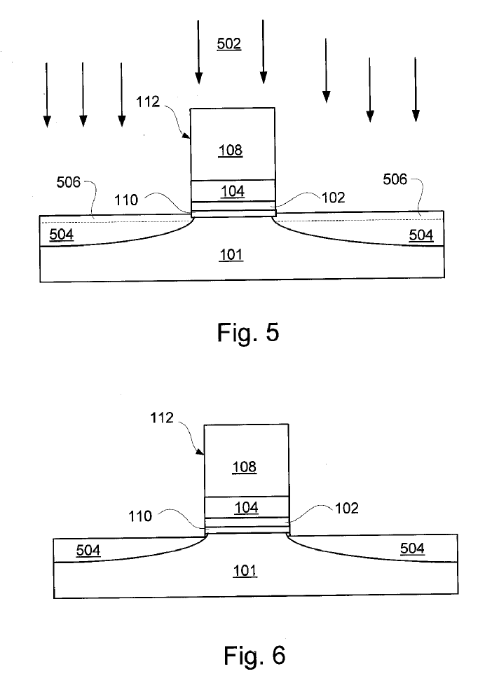

FIG. 6 is a cross sectional side view that illustrates the device 100 after at least a portion of the damaged region 506 has been removed, according to an embodiment. In an embodiment, between about 10 and about 40 angstroms may be removed from the top surface of the substrate 101. The damaged region 506 may contribute to transporting oxygen to a region beneath the gate stack, which may result the transitional oxide layer 110 growing thicker. Thus, removing at least a portion of the damaged region 506 may reduce the thickness of the transitional oxide layer 110 and improve the performance of the device. In some embodiments, the removal of at least a portion of the damaged region 506 may be omitted, as acceptable device performance levels may be reached without removing a portion of the damaged region 506.

FIG. 7 is a cross sectional side view that illustrates a blanket layer of spacer material 702 formed on the gate stack 102, 104, 108 and substrate 101, according to an embodiment. In an embodiment, the material of the blanket spacer layer 702 may be substantially free of oxygen. In an embodiment, the blanket spacer layer 702 may comprise a nitride material such as a carbon doped nitride, a stoichiometric silicon nitride, or another material. The blanket spacer layer 702 may be deposited by chemical or physical vapor deposition, atomic layer deposition, plasma enhanced chemical vapor deposition, or other methods.

In an embodiment, the blanket spacer layer 702 may be formed in a manner to prevent an increase in the thickness of the transitional oxide layer 110. In an embodiment, the substrate 101 and gate stack 102, 104, 108 may be inserted into a chamber in which the blanket spacer layer 702 may be deposited. The chamber and/or device 100 may be at a temperature of about 400 degrees Celsius or below at this point, which is low enough that little to no oxygen will react with the substrate 101 to increase the thickness of the oxide layer 110 or form birds beak or other lateral oxidation structures. Once the substrate 101 and gate stack 102, 104, 108 are sealed in the chamber, substantially all oxygen may be removed from the chamber. After purging the oxygen, the temperature may be raised and the blanket spacer layer 702 deposited. In an embodiment, this temperature may be between about 580 degrees Celsius and about 600 degrees Celsius. The temperature may be raised to a level that could potentially cause oxygen to react with the substrate 101 to form a thicker oxide layer 110 and/or form an oxide layer on the sidewalls and top of the gate stack 102, 104, 108. However, as the oxygen has been purged, these reactions may be avoided. Thus, the blanket spacer layer 702 may be formed without an oxide layer between the blanket spacer layer 702 and sidewalls of the gate stack 102, 104, 108 and without an oxide layer between the blanket spacer layer 702 and the top surface of the substrate 101. Further, the thickness of the transitional oxide layer 110 may remain substantially unchanged before and after the deposition of the blanket spacer layer 702, and lateral oxidation and birds beak structures may be substantially entirely avoided. In an embodiment, the device 100 may be kept in at least one of a substantially oxygen-free environment and below about 500 degrees Celsius after patterning the blanket layers 302, 304, 308 to form the gate stack and formation of the blanket spacer layer 702 that seals the gate stack from the environment.

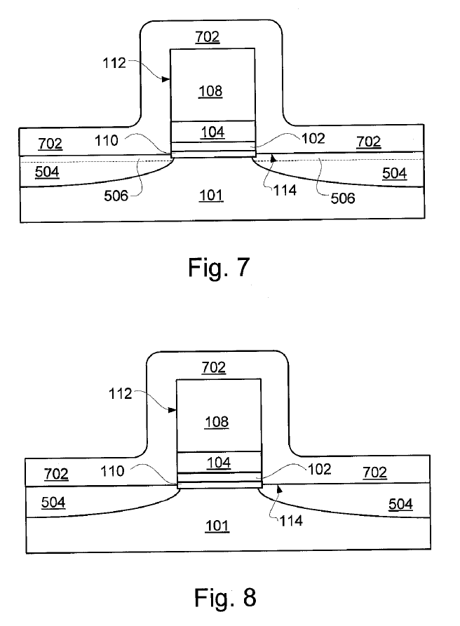

FIG. 8 is a cross sectional side view that illustrates the device 100 after it has been annealed to recrystallize some or all of the remaining amorphous regions 506 of the substrate 101, according to one embodiment of the present invention. In an embodiment, the device 100 may be annealed at a temperature between about 500 and about 1100 degrees Celsius. In an embodiment, the device 100 may be annealed at a temperature of about 1000 degrees Celsius. In an embodiment, the device 100 may be flash annealed, during which a local temperature may reach 1250 degrees Celsius. Other annealing temperatures may be used in other embodiments. During the annealing process, the blanket spacer layer 702 may help prevent formation of additional thickness of the oxide layer 110. Absent the blanket spacer layer 702, the high temperature of the annealing process may cause rapid formation of a thick layer of oxide 110 beneath the gate stack 102, 104, 105, or formation of lateral oxidation structures, reducing the performance of the device. Annealing the substrate 101 to recrystallize the amorphous regions 506 may remove a transport pathway by which oxygen could reach the oxide layer 110 in subsequent processes and make it thicker. Thus, annealing the substrate 101 may prevent device performance degradation.

The blanket spacer layer 702 may at least partially, if not completely, prevent oxygen from reaching regions beneath the blanket spacer layer 702 during such high temperature processes as annealing or other additional processes. The blanket spacer layer 702 may seal the thin oxide layer 110 from oxygen-containing structures and/or ambient oxygen in further process steps. This prevention of oxygen transport beneath the gate stack 102, 104, 108 may at least partially prevent oxidation of the substrate 101, which could result in the formation of additional undesired oxide 110, such as silicon oxide, beneath the gate stack 102, 104, 108 and/or formation of lateral oxide structures such as birds beak structures. Such an undesired oxide could degrade the performance of the device if its formation is not prevented. Spacers 106 may be formed from the blanket spacer layer 702, resulting in the device illustrated in FIG. 1. Any suitable method may be used to form the spacers 106.

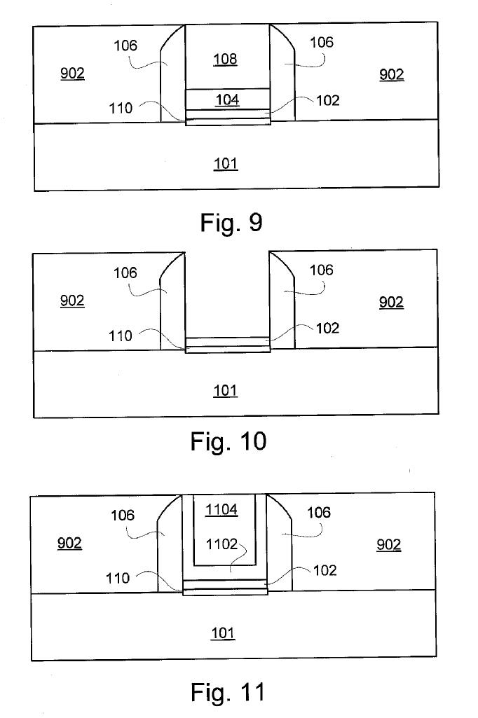

FIG. 9 is a cross sectional side view that illustrates an ILD (interlayer dielectric) layer 902 formed and planarized on the device 100 of FIG. 1, according to one embodiment of the present invention. Any suitable method may be used to form and planarize the ILD layer 902. In an embodiment, because the spacers 106 seal the oxide 110 away from oxygen, and the amorphous region 506 has been recrystallized to remove an oxygen transport pathway, high temperature processes and/or processes with ambient oxygen may be performed without substantially increasing the thickness of the oxide layer 110. Also, as the spacers 106 provide a seal, regions between the sidewalls of the gate stack 102, 104, 108 and the spacers 106, and between the spacers 106 and the top surface of the substrate 101 may be substantially free of an oxide. The ILD 902 may be in direct contact with the spacers 106 and the spacers 106 may in turn be in direct contact with the one or more of the high-k dielectric layer 102, the metal gate electrode 104, and the second electrode layer 108.

FIG. 10 is a cross sectional side view that illustrates removal of the first and second electrodes 104, 108, according to one embodiment of the present invention. In an embodiment, the first and second electrodes 104, 108 may be removed and later replaced by one or more replacement electrode layers. In another embodiment, the first electrode layer 104, which may be a metal electrode layer 104, may be left in place and only the second electrode layer 108 removed.

FIG. 11 is a cross sectional side view that illustrates replacement of the first and second electrode layers 104, 108 with first and second replacement electrode layers 1102, 1104. In an embodiment, the first replacement electrode layer 1102 may comprise a metal gate electrode material, although in other embodiments other materials may be used. The first replacement electrode layer 1102 may be conformal to the trench created by removing the first and second electrode layers 104, 108. In another embodiment, the first electrode layer 104 may remain in place rather than being removed, and only the second electrode layer 108 removed and replaced. In other embodiments with other arrangements of electrode layers, one or more of the electrode layers may be removed and replaced. Any removed layers may be replaced with an equal or different number of replacement layers.

In another embodiment, the sacrificial gate electrode removal and replacement processes shown in FIGS. 10 and 11 may be omitted. In such embodiments, the gate electrode or electrodes 104, 108 are not sacrificial gate electrodes to be removed and replaced, but are instead left in place in the final device.

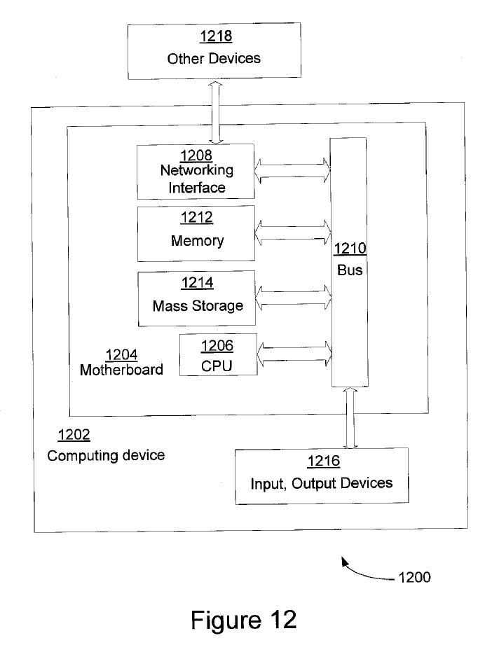

FIG. 12 illustrates a system 1200 in accordance with one embodiment of the present invention. One or more devices formed with the blanket spacer layer 702 and post-recrystallization of the substrate 101 spacers 106 that seal the under-gate-stack region from oxygen to prevent oxide layer 110 growth as described above may be included in the system 1200 of FIG. 12. As illustrated, for the embodiment, system 1200 includes a computing device 1202 for processing data. Computing device 1202 may include a motherboard 1204. Coupled to or part of the motherboard 1204 may be in particular a processor 1206, and a networking interface 1208 coupled to a bus 1210. A chipset may form part or all of the bus 1210. The processor 1206, chipset, and/or other parts of the system 1200 may include one or more devices 100 described above.

Depending on the applications, system 1200 may include other components, including but are not limited to volatile and non-volatile memory 1212, a graphics processor (integrated with the motherboard 1204 or connected to the motherboard as a separate removable component such as an AGP or PCI-E graphics processor), a digital signal processor, a crypto processor, mass storage 1214 (such as hard disk, compact disk (CD), digital versatile disk (DVD) and so forth), input and/or output devices 1216, and so forth.

In various embodiments, system 1200 may be a personal digital assistant (PDA), a mobile phone, a tablet computing device, a laptop computing device, a desktop computing device, a set-top box, an entertainment control unit, a digital camera, a digital video recorder, a CD player, a DVD player, or other digital device of the like.

Any of one or more of the components 1206, 1214, etc. in FIG. 12 may include one or more devices with the capping layer 302 as described herein. For example, a transistor device 100 may be part of the CPU 1206, motherboard 1204, graphics processor, digital signal processor, or other devices.

The foregoing description of the embodiments of the invention has been presented for the purposes of illustration and description. It is not intended to be exhaustive or to limit the invention to the precise forms disclosed. This description and the claims following include terms, such as left, right, top, bottom, over, under, upper, lower, first, second, etc. that are used for descriptive purposes only and are not to be construed as limiting. For example, terms designating relative vertical position refer to a situation where a device side (or active surface) of a substrate or integrated circuit is the “top” surface of that substrate; the substrate may actually be in any orientation so that a “top” side of a substrate may be lower than the “bottom” side in a standard terrestrial frame of reference and stilt fall within the meaning of the term “top.” The term “on” as used herein (including in the claims) does not indicate that a first layer “on” a second layer is directly on and in immediate contact with the second layer unless such is specifically stated; there may be a third layer or other structure between the first layer and the second layer on the first layer. The embodiments of a device or article described herein can be manufactured, used, or shipped in a number of positions and orientations. Persons skilled in the relevant art can appreciate that many modifications and variations are possible in light of the above teaching. Persons skilled in the art will recognize various equivalent combinations and substitutions for various components shown in the Figures. It is therefore intended that the scope of the invention be limited not by this detailed description, but rather by the claims appended hereto.

I claim:

1. A semiconductor device, comprising:
a substrate;
a high-k gate dielectric layer on the substrate;
a metal gate electrode on the high-k gate dielectric layer; and
spacers on either side of and adjacent to the metal gate electrode and high-k dielectric layer, extending a distance away from the metal gate electrode and high-k dielectric layer on the substrate, wherein there is substantially no oxide layer between the spacers and the metal gate electrode, between the spacers and the high-k dielectric layer, or between the spacers and the substrate.

2. The device of claim 1, wherein the spacers consist of a substantially oxygen-free material.

3. The device of claim 1, wherein there is substantially no birds beak structure between the high-k gate dielectric and the substrate.

4. The device of claim 1, wherein there is substantially no birds beak structure between the high-k gate dielectric and the metal gate electrode.

5. The device of claim 1, wherein the spacers are in direct contact with the substrate layer, the high-k gate dielectric layer, and the metal gate electrode.

6. The device of claim 1, further comprising an ILD layer that extends substantially from the substrate to a top of the spacers.

7. The device of claim 6, wherein the spacers are in direct contact with the substrate layer, the high-k gate dielectric layer, and the metal gate electrode, and are further in direct contact with the ILD layer.

8. A method for making a semiconductor device, comprising:
forming a blanket high-k gate dielectric layer on a semiconductor substrate;
forming a blanket gate electrode layer on the blanket high-k gate dielectric layer;
patterning the blanket high-k gate dielectric layer and blanket gate electrode layer to form a patterned gate stack having a top, a first side, and a second side;
forming a blanket spacer layer substantially free of oxygen on a top surface of the substrate, and the top and first and second sides of the patterned gate stack; and
wherein, from a first time at which the patterned gate stack is formed to a second time at which the blanket spacer layer is formed, the environment around the substrate has at least one of the parameters selected from the group consisting of: being substantially free of oxygen and being below about 500 degrees Celsius.

9. The method of claim 8, wherein forming a blanket spacer layer comprises:
inserting the substrate into a deposition chamber, the deposition chamber having a temperature of about 400 degrees Celsius or less when the substrate is inserted;
purging substantially all of the oxygen from the deposition chamber after the substrate has been inserted;
heating, after purging substantially all of the oxygen from the deposition chamber, the substrate and the deposition chamber to at least about 550 degrees Celsius; and
depositing the blanket spacer layer.

10. The method of claim 9, wherein after deposition of the blanket spacer layer there is substantially no oxide layer between the blanket spacer layer and the substrate, or between the blanket spacer layer and the patterned gate stack.

11. The method of claim 8, further comprising implanting ions into the substrate to form tip junction regions prior to forming the blanket spacer layer.

12. The method of claim 11, wherein implanting ions into the substrate results in a damaged amorphous region at a top surface of the substrate, further comprising removing at least some of the damaged amorphous region of the substrate after implanting ions into the substrate and before forming the blanket spacer layer.

13. The method of claim 12, further comprising annealing the substrate after removing at least some of the damaged amorphous region of the substrate.

14. The method of claim 11, wherein implanting ions into the substrate results in a damaged amorphous region at a top surface of the substrate, further comprising annealing the substrate to at least partially recrystallize the damaged amorphous region.

15. The method of claim 8, further comprising patterning the blanket spacer layer to form spacers adjacent the first and second sides of the patterned gate stack, the spacers forming a seal to prevent oxygen from reaching the volume between the high-k dielectric layer and the substrate.

16. The method of claim 8, wherein the spacer layer comprises a nitride material.

17. A method to form a transistor with substantially no oxide layer between spacers and a gate stack, comprising:
forming a patterned gate stack including a high-k gate dielectric layer and a gate electrode layer, on a substrate;
implanting ions into the substrate to form source, drain, and tip regions in the substrate adjacent sides of the patterned gate stack, the ion implantation resulting in amorphization of a region the substrate;
forming spacers substantially free of oxygen adjacent the sides of the patterned gate stack, wherein there is substantially no oxide layer between the spacers and the patterned gate stack or between the spacers and the substrate; and
forming an interlayer dielectric layer on the substrate adjacent the spacers, wherein the interlayer dielectric layer is in direct contact with the spacers and the spacers are in direct contact with the high-k gate dielectric layer.

18. The method of claim 17, wherein forming the spacers comprises:
inserting the substrate with the patterned gate stack into a deposition chamber, the deposition chamber having a temperature of about 400 degrees Celsius or less when the substrate is inserted;
purging substantially all of the oxygen from the deposition chamber after the substrate has been inserted;
heating, after purging substantially all of the oxygen from the deposition chamber, the substrate and the deposition chamber to at least about 550 degrees Celsius;
depositing a blanket spacer layer; and
removing portions of the blanket spacer layer to leave the spacers behind.

19. The method of claim 18, wherein the implanting ions into the substrate results in a damaged region at a top surface of the substrate, further comprising removing at least some of the damaged amorphous region of the substrate after implanting ions into the substrate and before forming the blanket spacer layer.

20. The method of claim 18, further comprising annealing the substrate to recrystallize the amorphized region of the substrate after depositing the blanket spacer layer and prior to removing portions of the blanket spacer leaving the spacers behind.
